(19) United States
(12) Patent Application Publication
(10) Pub. No.: US 2025/0146179 A1
(43) Pub. Date: May 8, 2025

(54) COMPOSITE SUBSTRATE, AND SUBSTRATE FOR EPITAXIALLY GROWING GROUP 13 ELEMENT NITRIDE

(71) Applicant: NGK INSULATORS, LTD., Nagoya-shi (JP)

(72) Inventors: Yoshitaka KURAOKA, Okazaki-shi (JP); Takashi YOSHINO, Ama-shi (JP)

(21) Appl. No.: 19/004,891

(22) Filed: Dec. 30, 2024

Related U.S. Application Data
(63) Continuation of application No. PCT/JP2023/014345, filed on Apr. 7, 2023.

(30) Foreign Application Priority Data
Jun. 30, 2022 (JP) 2022-105605

(51) Int. Cl. C30B 29/68; C30B 25/18; C30B 29/40; H01L 21/02

(52) U.S. Cl. CPC C30B 29/68; C30B 25/183; C30B 29/406; H01L 21/02389

(57) ABSTRACT

A composite substrate has a group 13 nitride semiconductor substrate having a first main surface and a second main surface and a supporting substrate having a bonding surface bonded with the first main surface of the group 13 nitride semiconductor substrate. The supporting substrate has a bonding region composed of silicon carbide having an average micropipe density of 10 cm⁻² or higher and 100 cm⁻² or lower at the bonding surface of the supporting substrate or composed of synthetic diamond having an atomic ratio of nitrogen to carbon atoms of 500 ppm or higher and 2000 ppm or lower.

### CROSS-REFERENCE TO RELATED APPLICATIONS

This application is a continuation application of PCT/JP 2023/014345, filed Apr. 7, 2023, which claims priority to Japanese Application No. JP 2022-105605 filed on Jun. 30, 2022, the entire contents all of which are incorporated hereby by reference.

### TECHNICAL FIELD

The present invention is related to a composite substrate including a group 13 nitride semiconductor substrate and a substrate for epitaxially growing a group 13 nitride.

### BACKGROUND ARTS

As a group 13 nitride semiconductor has a wide band gap of direct transition type, a high breakdown electric field and a high saturated electron velocity, the development as a semiconductor material for a high frequency/high power electronic device has been actively performed. As the representative electronic device including a group 13 nitride semiconductor, a high electron mobility transistor (HEMT) is known. Recently, the development of an HEMT device including an epitaxial growth group 13 nitride substrate, such as gallium nitride, with epitaxially grown channel layer exhibiting small lattice distortion has been made, as it is expected high performance and high reliability. Such group 13 nitride substrate applied as epitaxial growth substrate is produced by vapor phase or liquid phase methods.

The group 13 nitride substrate applied for epitaxial growth of an HEMT device preferably has a sufficiently high resistivity. Then, it is known that group 13 nitride doped with iron or manganese has a relatively high resistivity (patent document 1).

When a transition metal such as iron or manganese is doped into group 13 nitride as patent document 1, it is obtained a group 13 nitride substrate having a high resistivity. In the case that a gallium nitride layer is epitaxially grown on an epitaxial growth surface of the substrate, for example, the dislocation density is lower, compared with those of gallium nitride layers grown on seed substrates composed of a high resistance carbon nitride substrate of sapphire substrate. Thus, particularly when an HEMT structure is formed thereon, it is expected that dislocations contained in the channel layer (gallium nitride layer) is suppressed, that current collapse phenomenon or the like due to internal cause of gallium nitride crystal is suppressed and that the reduction of current gain is minimized, resulting in high reliability.

Further, according to patent document 2, research has been conducted to adhere a supporting substrate, composed of a material whose thermal conductivity is higher than that of a group 13 nitride semiconductor, onto a main surface of a group 13 nitride semiconductor substrate to prepare a composite substrate and to grow an epitaxial layer on the composite substrate. As the material of the supporting substrate, it has been studied a material whose thermal conductivity is higher than that of the material of the group 13 nitride semiconductor substrate and whose difference of thermal expansion coefficient is smaller. Specifically, it is described a composite substrate produced by adhering a thermally conductive supporting substrate composed of silicon carbide or diamond having a high thermal conductivity onto the group 13 nitride semiconductor substrate.

### PATENT DOCUMENTS

(Patent document 1) Japanese patent publication No. 2010-168226 A
(Patent document 2) Japanese patent publication No. 2008-300562A

### SUMMARY OF THE INVENTION

On the other hand, in the case that the material of the supporting substrate adhered onto the group 13 nitride semiconductor substrate is silicon carbide or diamond as described in patent document 2, the warpage of the composite substrate tends to occur after an epitaxial film is grown on the group 13 nitride semiconductor substrate, and in-plane variation of sheet resistance may occur after the HEMT structure is formed on the composite substrate through epitaxial growth. As a result, for example, in-plane variation of characteristics of the HEMT device may be generated.

An object of the present invention is to provide a composite substrate having a group 13 nitride semiconductor substrate and a supporting substrate bonded with the group 13 nitride semiconductor substrate, to suppress the warpage of the composite substrate when an epitaxial film is grown on the group 13 nitride semiconductor substrate and to suppress the in-plane variation of the sheet resistance of an HEMT structure formed on the composite substrate through epitaxial growth.

The present invention provides a composite substrate comprising:
a group 13 nitride semiconductor substrate having a first main surface and a second main surface; and
a supporting substrate comprising a bonding surface bonded with said first main surface of said group 13 nitride semiconductor substrate,
wherein said supporting substrate comprises a bonding region, and
wherein said bonding region is composed of silicon carbide having an average micropipe density of 10 cm⁻² or higher and 100 cm⁻² or lower at said bonding surface of said supporting substrate or composed of synthetic diamond having an atomic ratio of nitrogen to carbon atoms of 500 ppm or higher and 2000 ppm or lower.

Further, the present invention provides a substrate for epitaxially growing a group 13 nitride,
wherein said substrate comprises said composite substrate and
wherein said second main surface comprises a surface for epitaxially growing said group 13 nitride.

The present inventors studied the phenomenon that the warping of the composite substrate tends to occur and in-plane variation of sheet resistance is generated in an HEMT structure epitaxially formed on the composite substrate when an epitaxial film is grown on the group 13 nitride semiconductor substrate. As a result, the following findings were provided.

That is, for example, in the case that a group 13 nitride is grown by MOCVD method, heat treatment at 900 to 1100° C. is required. In this case, even when the material of the supporting substrate to be adhered to the group 13 nitride semiconductor substrate is made diamond or silicon carbide and the thermal expansion coefficients are matched as possible, it is proved that the warping of the composite substrate is generated at room temperature due to the stress of the formed epitaxial film after the epitaxial growth. As the warping of the composite substrate occurs, during the step of exposure for forming electrodes on the epitaxial film, in-plane variation of focus is provided so that it is difficult to form the electrodes having predetermined shapes and dimensions. The amount of warping is preferably 20 μm or less. It is further proved that the in-plane variation of characteristics of the epitaxial film is provided and particularly in-plane variation of sheet resistance is provided responsive to the warping of the composite substrate after the growth of the epitaxial film.

Thus, the present inventors have further studied the material of the supporting substrate to be adhered to the group 13 nitride semiconductor substrate. Here, conventional dense diamond or silicon carbide with good crystallinity has been applied as the material of the supporting substrate. It is then tried to change them to silicon carbide having a high average micropipe density of 10 cm⁻² or higher at the bonding surface of the supporting substrate or to synthetic diamond having a high impurity content in which an atomic ratio of nitrogen to carbon atoms is 500 ppm or higher. As a result, in the case that an epitaxial film is grown on the group 13 nitride semiconductor substrate, it is found that the warping of the composite substrate is suppressed and in-plane variation of resistance of an HEMT structure formed on the composite substrate through epitaxial growth is suppressed. The present invention was thus made.

### BRIEF DESCRIPTION OF THE DRAWINGS

FIG. 1A is a schematic view showing a composite substrate 3 according to an embodiment of the present invention, and FIG. 1B is a schematic view showing a HEMT device 10.

FIG. 2 is a plan view showing measurement points of micropipe densities and of variation of sheet resistance values.

### MODES FOR CARRYING OUT THE INVENTION

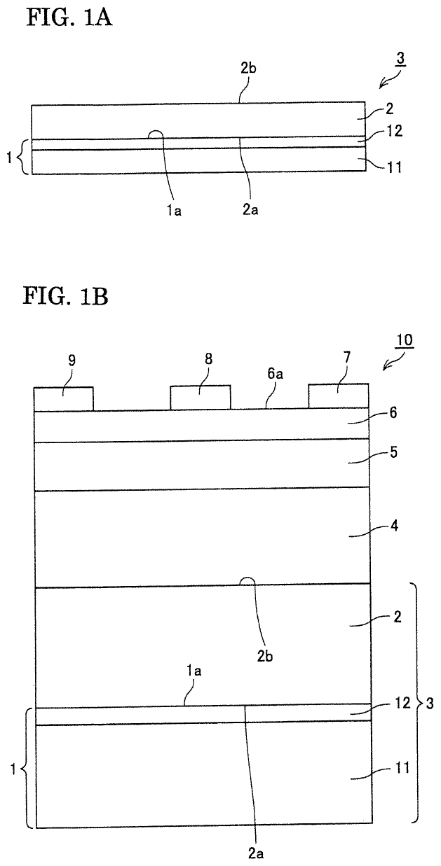

FIG. 1A is a schematic view showing a composite substrate 3 according to an embodiment of the present invention, and FIG. 1B is a schematic view showing an HEMT device 10.

A group 13 nitride semiconductor substrate 2 has a first main surface 2a and a second main surface 2b facing the opposite side of the first main surface 2a. A supporting substrate 1 is composed of an underlying substrate 11 and a bonding region 12, and a bonding surface 1a of the supporting substrate 1 is bonded with the first main surface 2a of the group 13 nitride semiconductor substrate 2. The second main surface 2b of the group 13 nitride semiconductor substrate 2 is selected as a surface for epitaxial growth, and an epitaxial film is grown on the second main surface 2b. Specifically, according to the present example, a buffer layer 4 is grown on the second main surface 2b of the group 13 nitride semiconductor substrate 2, a channel layer 5 is grown on the buffer layer 4, and a barrier layer 6 is grown on the channel layer 5. Predetermined electrodes may be provided on a surface 6a of the barrier layer 6. According to the present example, a source electrode 9, gate electrode 8 and drain electrode 7 are formed.

As the group 13 nitride semiconductor substrate of the present invention is applied as a template substrate for epitaxial growth, it is possible to realize an HEMT device capable of operating at a high output power. By applying such HEMT device, it is possible to realize a power amplifier operating at a high output power, high frequency and high efficiency required for base stations for next-generation wireless communication.

### (Group 13 Nitride Semiconductor Substrate)

The group 13 nitride semiconductor substrate is composed of a group 13 nitride semiconductor.

The group 13 element means a group 13 element defined is IUPAC, and may more preferably be gallium, aluminum and/or indium. Further, the group 13 nitride semiconductor may preferably be a group 13 nitride semiconductor selected from gallium nitride, aluminum nitride, indium nitride or the mixed crystals thereof. More specifically, GaN, AlN, InN, GaₓAl₁₋ₓN (0<x<1), GaₓIn₁₋ₓN (0<x<1), AlₓIn₁₋ₓN (0<x<1) and GaₓAl_{y}In_{z}N (0<x<1, 0<y<1, x+y+z=1) are listed.

According to a preferred embodiment, the resistivity of the group 13 nitride semiconductor substrate at room temperature is 1×10⁶ Ω·cm or higher. That is, the group 13 nitride semiconductor substrate is of semi-insulating. On the viewpoint, the resistivity of the group 13 nitride semiconductor substrate at room temperature may preferably be 1×10⁷ Ω·cm or higher and more preferably be 1×10⁹ Ω·cm or higher. Further, the resistivity of the group 13 nitride semiconductor substrate at room temperature may be 1×10¹³ Ω·cm or lower in many cases.

Further, according to a preferred embodiment, the dislocation density of the second main surface of the group 13 nitride semiconductor substrate is 10⁶ cm⁻² or lower. The dislocation density may preferably be 10⁵ cm⁻² or lower. Further, the dislocation density may be 10⁵ cm⁻² or higher on a practical viewpoint in many cases.

The second main surface (epitaxial growth surface) of the group 13 nitride semiconductor substrate may be a group 13 element polar surface or nitrogen polar surface.

According to a preferred embodiment, one or more elements selected from the group consisting of manganese, iron and zinc are doped in the group 13 nitride semiconductor substrate. It is thereby possible to improve the resistivity of the group 13 nitride semiconductor substrate.

According to a preferred embodiment, the concentration of manganese of the group 13 nitride semiconductor may preferably be 1×10¹⁸ atoms/cm³ to 1×10¹⁹ atoms/cm³ and more preferably be 2×10¹⁸ atoms/cm³ to 5×10¹⁸ atoms/cm³.

According to a preferred embodiment, the concentration of iron of the group 13 nitride semiconductor may preferably be 8×10¹⁶ atoms/cm³ to 5×10¹⁹ atoms/cm³, and more preferably be 5×10¹⁷ atoms/cm³ to 1×10¹⁹ atoms/cm³.

Further, according to a preferred embodiment, the concentration of zinc of the group 13 nitride semiconductor may preferably be 1×10¹⁷ atoms/cm³ to 3×10¹⁸ atoms/cm³ and more preferably be 2×10¹⁷ atoms/cm³ to 1×10¹⁸ atoms/cm³. Further, the concentration of manganese, concentration of iron and concentration of zinc of the group 13 nitride semiconductor are to be measured by SIMS (Secondary ion mass spectroscopy).

Further, the group 13 nitride semiconductor may contain an element other than zinc, iron and manganese. Such element may be hydrogen (H), oxygen (O), silicon (Si), carbon (C) or the like, for example.

### (Production of Group 13 Nitride Semiconductor Substrate)

The method of producing the group 13 nitride semiconductor substrate may be a vapor phase method such as Metal Organic Chemical Vapor Deposition (MOCVD) method, hydride vapor phase epitaxy (HVPE) method, pulse-excited deposition (PXD) method, MBE method, sublimation method or the like, or a liquid phase method such as ammonothermal method, flux method or the like. More preferably, the group 13 nitride semiconductor substrate is that produced by flux method.

In the case of flux method, it is preferred to immerse a seed substrate in flux containing manganese, iron and/or zinc and to grow the group 13 nitride on the seed substrate under atmosphere of a high temperature and high pressure to obtain the group 13 nitride semiconductor substrate. More preferably, it is preferred to provide a seed crystal film on a surface of a supporting substrate such as sapphire, group 13 nitride single crystal or the like to provide the seed substrate and to grow the group 13 nitride semiconductor on the seed crystal film.

As the material of the seed crystal film, AlxGa1-xN (0≤x≤1) and InxGa1-xN (0≤x≤1) are listed as preferred examples, and gallium nitride is particularly preferred.

The method of growth of the seed crystal film may preferably be a vapor phase deposition method, and Metal Organic Chemical Vapor Deposition (MOCVD) method, hydride vapor phase deposition (HVPE) method, pulse-excited deposition (PXD) method, MBE method and sublimation method are listed. Metal Organic Chemical Vapor Deposition method is most preferred. Further, the growth temperature may preferably be 950 to 1200° C.

In the case that the group 13 nitride semiconductor is grown by flux method, the kind of the flux is not particularly limited, as far as the group 13 nitride semiconductor can be grown. According to a preferred embodiment, the flux contains at least one of an alkali metal and alkaline earth metal and the flux containing sodium metal is particularly preferred.

A raw material substance of a metal is mixed with the flux and applied. The raw material substrate of a metal may be a single metal, alloy or metal compound, and the single metal is preferred on the viewpoint of handling.

The growth temperature and holding time for the growth of the group 13 nitride semiconductor by flux method are not particularly limited and may be appropriately changed depending on the composition of the flux. For example, in the case that gallium nitride crystal is grown by applying the flux containing sodium or lithium, the growth temperature may preferably be 800 to 950° C. and more preferably be 850 to 900° C.

In the flux method, the group 13 nitride semiconductor is grown under an atmospheric gas containing nitrogen atoms. The atmospheric gas may preferably be nitrogen gas and may be ammonia. Although the pressure of the atmospheric gas is not particularly limited and may preferably be 10 atm or higher and more preferably be 30 atm or higher on the viewpoint of preventing the evaporation of the flux. However, as the pressure is higher, the scale of the system becomes larger. Thus, the total pressure of the atmosphere may preferably be 2000 atm or lower and more preferably be 500 atm or lower. Although the gas other than the gas including nitrogen atom in the atmosphere is not limited, an inert gas is preferred, and argon, helium or neon is particularly preferred.

According to a particularly preferred embodiment, a seed crystal film composed of gallium nitride is grown on a sapphire substrate by MOCVD method to obtain a seed substrate. The seed substrate is mounted in a crucible and 10 to 50 mol % of Ga metal, 50 to 90 mass parts of Na metal and 0.0001 to 1 mol % of Mn metal, Fe metal or Zn metal are then filled in the crucible. The added amounts of the Mn metal, Fe metal and Zn metal are appropriately adjusted in the ranges described above to control the respective concentrations of the group 13 nitride semiconductor. The crucible is contained in a heating furnace, the temperature in the furnace is made 800 to 950° C., the pressure in the furnace is made 3 to 5 MPa, the heating is performed for 20 to 400 hours and the temperature is then cooled to room temperature. After the termination of the cooling, the crucible is drawn out of the furnace.

The thus obtained gallium nitride is polished by diamond abrasive grains to flatten the surface.

### (Supporting Substrate)

The supporting substrate is to be bonded with the first main surface of the group 13 nitride semiconductor substrate.

Here, the bonding region of the supporting substrate is composed of silicon carbide having an average micropipe density of 10 cm⁻² or higher and 100 cm⁻² or lower on the bonding surface of the supporting substrate, or composed of synthetic diamond having an atomic ratio of nitrogen to carbon atoms of 500 ppm or higher and 2000 ppm or lower.

As silicon carbide providing the material of the bonding region of the supporting substrate, low quality silicon carbide having many dislocations, defects or micropipes and referred to as so-called dummy grade is applied. The warping of the composite substrate can be thereby suppressed and in-plane variation of sheet resistance of an HEMT structure grown on the composite substrate through epitaxial growth can be thereby suppressed, when an epitaxial film is grown on the group 13 nitride semiconductor substrate.

Specifically, the bonding region of the supporting substrate is composed of silicon carbide having a micropipe density of 10 cm⁻² or higher and 100 cm⁻² or lower at the bonding surface. By increasing the average micropipe density of silicon carbide to 10 cm⁻² or higher, the warping of the composite substrate after growth of the HEMT structure can be reduced and the in-plane variation of sheet resistance of the HEMT structure can be reduced. On the viewpoint, the average micropipe density of silicon carbide at the bonding surface may preferably be made 30 cm⁻² or higher. Further, in the case that the average micropipe density of silicon carbide exceeds 100 cm⁻², the warping of the composite substrate after the HEMT structure is grown can be reduced. However, it is proved that the in-plane variation of sheet resistance of the HEMT structure is rather increased. The average micropipe density of silicon carbide is thus made 100 cm⁻² or lower and may preferably be made 70 cm⁻² or lower.

As the method of producing the silicon carbide, sublimation method and high-temperature chemical vapor deposition (CVD) method are exemplified. Various kinds of polytypes of silicon carbide are present, any of the polytypes may be applied. Further, on the viewpoint of thermal conductivity and availability, 4H and 6H polytypes are preferred. Further, the silicon carbide may be single crystal or polycrystal. As it is preferred that the bonding surface is flat, single crystal is preferred on the viewpoint.

Further, in the ease that the bonding region of the supporting substrate is grown of the synthetic diamond as described above, as point-defects are generated inside of the bonding region due to the incorporation of nitrogen atoms. The warping of the composite substrate is thereby suppressed and in-plane variation of sheet resistance of the HEMT structure of the composite substrate is thereby suppressed, when the epitaxial film is grown on the group 13 nitride semiconductor substrate.

Specifically, the bonding region of the supporting substrate is composed of synthetic diamond having an atomic ratio of nitrogen to carbon atoms of 500 ppm or higher and 2000 ppm or lower. By increasing the atomic ratio of nitrogen to carbon atoms to 500 ppm or higher, it is possible to reduce the warping of the composite substrate after the epitaxial film is grown and to reduce the in-plane variation of the sheet resistance of the HEMT structure. On the viewpoint, the atomic ratio of nitrogen to carbon atoms may preferably be made 800 ppm or higher. Further, it was found that when the atomic ratio of nitrogen to carbon atoms exceeds 2000 ppm, the warping of the composite substrate after the growth of the HEMT structure can be reduced, but the in-plane variation of the sheet resistance of the HEMT structure increases. Thus, the atomic ratio of nitrogen to carbon atoms is made 2000 ppm or lower and may preferably be made 1500 ppm or lower. Further, for relaxing the stress uniformly in a plane, it is preferred that nitrogen atoms are uniformly dispersed in the synthetic diamond as isolated substitutional type impurity.

The method of producing the synthetic diamond applied in the present invention may be HPHT method, CVD method or the like, and CVD method is more preferred. Further, the synthetic diamond may be of single crystal or polycrystal. The bonding surface is preferably flat, and on the viewpoint, single crystal is preferred, as a flat surface is obtained by polishing.

For example, the whole of the supporting substrate 1 as shown in FIG. 1A may be composed of the silicon carbide or the synthetic diamond described above. That is, the whole of the underlying substrate 11 and bonding region 12 may be composed of the silicon carbide or synthetic diamond described above. However, it is not required that the whole of the supporting substrate is composed of the silicon carbide or synthetic diamond, and it is sufficient that at least the bonding region 12 including the bonding surface of the supporting substrate is composed of the silicon carbide or synthetic diamond described above. The “bonding region” means a region of a thickness of 100 μm starting from the bonding surface of the supporting substrate. In the case that the materials of the bonding region 12 and underlying substrate 11 are different from each other, the underlying substrate 11 may be composed of silicon single crystal, silicon polycrystal, sapphire single crystal, alumina polycrystalline body, or a single crystal or sintered body of aluminum nitride.

The bonding surface of the supporting substrate may preferably be made a flat surface by performing the flattening through polishing such as CMP. Alternatively, a thin film composed of the silicon carbide or synthetic diamond may be grown as a film on the bonding surface of the supporting substrate by CVD method to provide the flat surface. Further, the arithmetic average roughness Ra of the bonding surface of the supporting substrate may preferably be 5 nm or lower and more preferably be 0.5 nm or lower.

It is not generally preferred a device produced by epitaxial growth on silicon carbide having a high micropipe density or the synthetic diamond having a high nitrogen concentration, due to the deterioration of the properties. However, according to the structure of the present invention, as it is grown the epitaxial film operating as a functional layer of the device on the group 13 nitride semiconductor substrate of a low dislocation density bonded with the supporting substrate, the influence of the low-grade material of the supporting substrate does not directly exerted on the epitaxial film.

As to the group 13 nitride semiconductor substrate, on the viewpoint of suppressing the reduction of operational efficiency of the epitaxial film, for example HEMT element, formed on the epitaxial growth surface due to the temperature rise during the operation, it is preferred to shorten the distance between the supporting substrate and epitaxial film. On the viewpoint, the thickness of the group 13 nitride semiconductor substrate may preferably be 150 μm or less and more preferably be 50 μm or less. Further, as the group 13 nitride semiconductor substrate is bonded with the supporting substrate, the concern of the fracture is prevented, and the substrate can be easily handled even when the group 13 nitride semiconductor substrate is subjected to polishing to a thickness as thin as 150 μm or less. It is thus preferred to perform the polishing of the group 13 nitride semiconductor substrate after the bonding.

The bonding of the group 13 nitride semiconductor substrate supporting substrate may preferably be direct bonding and may be indirect bonding through an intermediate layer composed of an inorganic material resistive to a high temperature.

The direct bonding is performed by subjecting the bonding surface to wet cleaning to obtain a cleaned surface and by irradiating neutralized beam onto the bonding surface for the activation. A high-speed atomic beam source of saddle-field type is a preferred example as the beam source. Further, an electric voltage during the activation through the irradiation of the beam may preferably be made 0.5 to 2.0 kV, and the current may preferably be made 50 to 200 mA.

As to the indirect bonding, the intermediate layer may preferably be made of an SiOx series material (x=1 to 2) as the inorganic material. After the supporting substrate is subjected to plasma treatment, raw material gas containing a silicon compound is applied to grow an Siox series glass film of amorphous structure by plasma CVD method and the group 13 nitride semiconductor substrate is then bonded to an underlying substrate. As the raw material gas containing the silicon compound may be silane, disilane, hexamethyldisiloxane (HMDSO), tetramethyldisiloxane (TMDSO), methyltrimethoxysilane (MTMOS), methylsilane, dimethylsilane, trimethylsilane, diethylsilane or the like.

### (Growth of Epitaxial Film)

As the material of the epitaxial film grown on the second main surface of the group 13 nitride semiconductor substrate, gallium nitride, aluminum nitride, indium nitride or the mixed crystal thereof may be listed. Specifically, GaN, AlN, InN, GaₓAl₁₋ₓN (0<x<1), GaₓIn₁₋ₓN (0<x<1), AlₓIn₁₋ₓN (0<x<1), GaₓAl_{y}In₂N (0<x<1, 0<y<1, x+y+z=1) may be listed. Further, as the functional layer provided on the group 13 nitride semiconductor substrate, a channel layer, a buffer layer, a barrier layer, as well as a light-emitting layer, rectifying element layer and switching element layer may be listed.

For example, as shown in FIG. 1B, the buffer layer 4, channel layer 5 and barrier layer 6 are grown on the second main surface 2b of the group 13 nitride semiconductor substrate 2.

The growth of the buffer layer 4, channel layer 5 and barrier layer 6 can be performed by, for example, metal organic chemical vapor deposition (MOCVD) method. According to the growth of the layers with MOCVD method, metal organic raw material gases (TMG (trimethyl gallium), TMA (trimethyl aluminum), TMI (trimethyl indium) or the like) depending on the target composition, ammonia gas, hydrogen gas and nitrogen gas are supplied into a reactor of an MOCVD furnace, and the group 13 nitrides are subsequently generated by the vapor phase reaction of the metal organic raw material gases corresponding with the respective layers and ammonia gas while the group 13 nitride semiconductor substrate mounted in the reactor is heated at a predetermined temperature.

### Examples

### Experiment 1

### (Fabrication of Supporting Substrate 1 Composed of Silicon Carbide)

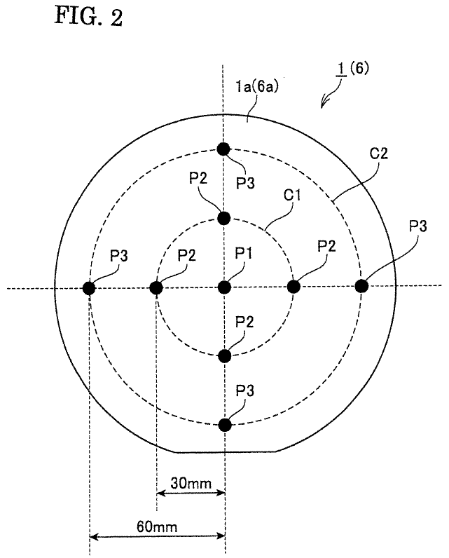

By applying sublimation method (PVT method), it was prepared a supporting substrate having a thickness of 0.5 mm, of 3-inches and composed of a semiconducting 4H-SiC single crystal, so that the vanadium concentration was adjusted at 1×10¹⁷ to 1×10¹⁸ cm⁻³. On the bonding surface 1a of the supporting substrate 1, composed of 4H-SiC single crystal, nine points shown in FIG. 2 were observed by a polarized light microscope, and the number of micropipes in 3 mm×4 mm region was counted to calculate the average micropipe density. Further, in FIG. 2, the practical center P1 of the bonding surface 1a, four points P2 on a circle C1 having a radius of 30 mm with respect to the center P1 and four points P3 on a circle C2 having a radius of 60 mm with respect to the center P1 were selected as points to be measured. The four points P2 on the circle C1 were positioned distant from each other by 90 degrees, respectively, and the points P3 on the circle C2 were distant from each other by 90 degrees. The average micropipe density at the bonding surface 1a of the supporting substrate 1 was changed as shown in table 1. Further, the average micropipe density was adjusted by changing the concentration of vanadium.

Further, the presence and absence of the micropipes can be confirmed by analyzing birefringence image observed by the polarized light microscope.

### (Fabrication of Gallium Nitride Substrate 2)

Next, it was produced a gallium nitride substrate composed Fe-doped gallium nitride of 3-inches. Specifically, a seed crystal film composed of gallium nitride and a thickness of 2 μm was formed on the surface of the c-plane sapphire substrate having a diameter of 3-inches to provide a seed substrate. A gallium nitride single crystal was formed on the seed substrate by Na flux method. Specifically, 50 grams of Ga metal, 100 grams of Na metal and Fe metal were placed in an alumina crucible, respectively, and the crucible was closed with an alumina lid. The crucible was contained in a heating furnace, the temperature inside of the furnace was made 850° C., the pressure inside of the furnace was made 4.0 MPa and the heating was performed over 100 hours, followed by cooling to room temperature. After the termination of the cooling, the alumina crucible was drawn out of the furnace to prove that brown gallium nitride single crystal was deposited on the surface of the seed substrate in a thickness of about 1000 μm.

The gallium nitride single crystal obtained in this manner was polished by diamond abrasive grains to flatten its surface, resulting in a total thickness of the gallium nitride single crystal formed on the underlying substrate was made 700 μm. The seed substrate was separated from the gallium nitride single crystal by laser lift-off method to obtain a gallium nitride substrate.

The first main surface and second main surface of the gallium nitride substrate were subjected to polishing to obtain a gallium nitride substrate having a thickness of 400 μm. As the in-plane resistivity of the bonding surface of the gallium nitride substrate was measured, a resistivity of 10⁷ Ω·cm or higher was obtained.

Further, the resistivity of each of the gallium nitride substrates was measured by capacitance method (“COREMA-WT” produced by SEMIMAP corporation).

### (Fabrication of Composite Substrate)

Then, the gallium nitride substrate 2 and each supporting substrate 1 described above were bonded with each other by direct bonding method. Specifically, the first main surface (nitrogen polarity surface) 2a of the gallium nitride substrate 2 and bonding surface (silicon polarity surface) 1a of the supporting substrate were subjected to surface activation, followed by the direct bonding. The second main surface 2b of the gallium nitride substrate 2 was made a gallium polarity surface and epitaxial growth surface. Further, the warping of each composite substrates 3 obtained was 5 μm or less.

### (Fabrication of HEMT Element)

Then, the HEMT structure shown in FIG. 1B was epitaxially grown by MOCVD method on the main surface 2b of the gallium nitride substrate 2 of the composite substrate. The composition and film thickness of each layer were as follows.

| | (Composition) | (film thickness: nm) |
|---|---|---|
| Buffer layer 4: | GaN | 500 |
| Channel layer 5: | GaN | 150 |
| Barrier layer 6: | AlGaN (Al ratio was 0.2): | film thickness was 20 nm |

### (Evaluation)

After growing the respective epitaxial films, the thus obtained HEMT structure was drawn out of the MOCVD equipment and the warping amount of the composite substrate with the HEMT structure grown was measured. The measurement was performed by means of “FT-17” produced by NIDEK to obtain SORI measurement values.

Further, the in-plane variation of the sheet resistance in the HEMT structure 10 was calculated. The sheet resistance was measured non-contact by a diameter of 14 mm measurement probe with “NC-80MAP produced by NAPSON CORPORATION. The nine points shown in FIG. 2 were selected as the measurement points. In FIG. 2, the practical center P1 of the surface 6a of the barrier layer 6, four points P2 on a circle C1 having a radius of 30 mm with respect to the center P1 and four points P3 on a circle C2 having a radius of 60 mm with respect to the center P1 were selected as points to be measured. The four points P2 on the circle C1 were positioned distant from each other by 90 degrees, respectively, and the points P3 on the circle C2 were distant from each other by 90 degrees. The following formula was applied for calculating the in-plane variation of the sheet resistance.

In-plane variation of sheet resistance=(maximum value of sheet resistances-minimum value of sheet resistances)/(minimum value of sheet resistances)

The results of measurement of the in-plane variation of the sheet resistance and warping amount were shown in Table 1.

TABLE 1

| | In-plane | |
|---|---|---|
| Average micropipe | variation of | Warping after |
| density of silicon | sheet | film-growth |
| carbide (cm⁻²) | resistance | (SORI) (μm) |
| 0.2 | 42% | 45 |
| 2 | 36% | 40 |
| 8 | 31% | 33 |
| 10 | 27% | 29 |
| 15 | 18% | 28 |
| 27 | 12% | 22 |
| 30 | 5.3% | 7 |
| 52 | 2.4% | 4 |
| 70 | 9.2% | 3 |
| 73 | 14% | 4 |
| 97 | 19% | 2 |
| 105 | 23% | 3 |

When the average micropipe density on the bonding surface of the silicon carbide, as the material of the supporting substrate, is 10 cm⁻² or higher, the in-plane variation of sheet resistance is small and the warping was reduced. On the viewpoint, the average micropipe density is more preferably 30 cm⁻² or higher. As to the reason why the in-plane variation of sheet resistance becomes large in the case that the average micropipe density is low, it is considered that in-plane variation is generated in the composition of Al or the like during the film-growth of the epitaxial film due to the large warping.

Further, when the average micropipe density of the silicon carbide, as the material of the supporting substrate, on the bonding surface is 100 cm⁻² or lower, the in-plane variation of the sheet resistance becomes small. On the viewpoint, the average micropipe density is more preferably 70 cm⁻² or lower. As the surface of the thus obtained barrier layer was observed by an atomic force microscope (AFM) in the case that the average micropipe density exceeds 100 cm⁻², microcracks were generated on the surface of the barrier layer, and the microcracks was proved to be unevenly distributed in the plane. It is considered as follows. In the case that the micropipe density is high, the micropipe density at the bonding surface of the supporting substrate composed of the silicon carbide is unevenly distributed and the relaxation of the stress between the bonding surface of the supporting substrate and first main surface (bonding surface) of the gallium nitride substrate becomes uneven in the plane, generating the microcracks. As a result, the secondary electron gas is suppressed at a low value at positions during the film-growth of the epitaxial film, so that the in-plane variation of the sheet resistance becomes large.

When the average micropipe density is 30 cm⁻² or higher and 70 cm⁻² or lower, the in-plane variation of the sheet resistance after the film-growth of the epitaxial film was proved to be less than 10%, and a SORI measurement value of less than 10 μm was obtained.

### Experiment 2

On the (100) plane of a silicon single crystal substrate of 3-inches, a monocrystalline synthetic diamond layer was uniformly grown to a thickness of 0.1 mm by CVD method, while adding a small amount of nitrogen gas. Then, the bonding surface of the synthetic diamond layer and the first main surface (nitrogen polarity surface) of the gallium nitride substrate were bonded with each other through direct bonding method. Then, the silicon single crystal substrate was removed by etching with fluoric acid. The composite substrate 3 of the supporting substrate 1 composed of the synthetic diamond and gallium nitride substrate was thereby obtained.

Here, two supporting substrates were produced simultaneously under the same condition, the nitrogen concentration in the diamond of one substrate was measured, while the other was subjected to the production of the composite substrate and the epitaxial growth step. The concentration of nitrogen was measured by SIMS. At this time, the measurements were performed in a depth of 30 μm at each of the nine points on the bonding surface shown in FIG. 2, and the average value was adopted.

Then, the buffer layer 4, carrier layer 5 and barrier layer 6 were grown as the experiment 1 to produce the HEMT structure 10. The thus obtained HEMT structure 10 was subjected to the measurement of the SORI measurement value and in-plane variation of the sheet resistance and the results were shown in Table 2.

TABLE 2

| Nitrogen content of | In-plane | |
|---|---|---|
| the synthetic | variation of | Warping after |
| diamond | sheet | film-growth |
| (ppm) | resistance | (SORI) (μm) |
| 100 | 128% | 100 |
| 200 | 84% | 53 |
| 400 | 32% | 35 |
| 500 | 19% | 28 |
| 600 | 15% | 25 |
| 700 | 11% | 22 |
| 800 | 5.6% | 18 |
| 1200 | 7.8% | 16 |
| 1500 | 8.9% | 15 |
| 2000 | 15% | 18 |
| 2100 | 21% | 13 |
| 2500 | 48% | 15 |

As a result, by increasing the nitrogen content of the synthetic diamond forming the supporting substrate to 500 ppm or higher through the addition of the nitrogen gas, the warping was reduced, and the in-plane variation of sheet resistance became smaller compared to conventional products. From this perspective, the nitrogen content of the synthetic diamond forming the supporting substrate may more preferably be made 800 ppm or higher. It is considered that increasing the nitrogen content of the synthetic diamond forming the supporting substrate increases micro-defects, resulting in the reduction of the warping and of the in-plane variation of the sheet resistance.

Further, in the case that the nitrogen content of the synthetic diamond forming the supporting substrate exceeds 2000 ppm, although the warping was small, the in-plane variation of the sheet resistance of the HEMT structure was increased and exceeds 20%. As the surface of the thus obtained barrier layer was observed by an atomic force microscope (AFM), the microcracks were presented on the surface of the barrier layer and the distribution of the microcracks was deviated in the plane. Thus, when the nitrogen content of the synthetic diamond is too high, it is considered as follows. The relaxation of the stress between the bonding surface of the supporting substrate and the first main surface (bonding surface) of the gallium nitride substrate becomes uneven in the plane. The microcracks are thereby generated so that there are positions at which the secondary electron gas is suppressed during the film-growth of the epitaxial film and the in-pane variation of the sheet resistance becomes larger.

When the nitrogen content of the material of the supporting substrate was 800 ppm or higher and 1500 ppm or lower, the in-plane variation of the sheet resistance of the HEMT structure was less than 10% and the SORI measurement value was less than 20 μm.

1. A composite substrate comprising:
a group 13 nitride semiconductor substrate comprising a first main surface and a second main surface; and
a supporting substrate having a bonding surface bonded with said first main surface of said group 13 nitride semiconductor substrate,
wherein said supporting substrate comprises a bonding region, and
wherein said bonding region is composed of silicon carbide having an average micropipe density of 10 cm⁻² or higher and 100 cm⁻² or lower at said bonding surface of said supporting substrate or composed of synthetic diamond having an atomic ratio of nitrogen to carbon atoms of 500 ppm or higher and 2000 ppm or lower.

2. The composite substrate of claim 1, wherein said group 13 nitride semiconductor substrate has a resistivity at room temperature of 10⁶ Ω·cm or higher.

3. The composite substrate of claim 1, wherein said said second main surface of said group 13 nitride semiconductor substrate has a dislocation density of 10⁶ cm⁻² or lower.

4. The composite substrate of claim 1, wherein said said second main surface of said group 13 nitride semiconductor substrate comprises a group 13 element polar surface or nitrogen polar surface.

5. The composite substrate of claim 1, wherein said group 13 nitride semiconductor substrate contains a dopant selected from the group consisting of manganese, iron and zinc.

6. The composite substrate of claim 1, wherein said first main surface of said group 13 nitride semiconductor substrate and said bonding surface of said supporting substrate are directly bonded.

7. The composite substrate of claim 1, comprising a bonding layer present between said first main surface of said group 13 nitride semiconductor substrate and said bonding surface of said supporting substrate.

8. A substrate for epitaxially growing a group 13 nitride, said substrate comprising said composite substrate of claim 1, wherein said second main surface comprises an epitaxial growth surface of said group 13 nitride.
